(19) United States
(12) Patent Application Publication
(10) Pub. No.: US 2024/0332059 A1
(43) Pub. Date: Oct. 3, 2024

(54) METHOD OF FABRICATING SEMICONDUCTOR DEVICE

(71) Applicant: Samsung Electronics Co., Ltd., Suwon-si (KR)

(72) Inventors: Youngin KIM, Suwon-si (KR); BYOUNGHO KWON, Suwon-si (KR); Yeil KIM, Suwon-si (KR); JONGHYUK PARK, Suwon-si (KR); JIN-WOO BAE, Suwon-si (KR); KYOUNGJOON SONG, Suwon-si (KR); MYUNGJAE JANG, Suwon-si (KR); Byungsoo JOO, Suwon-si (KR)

(21) Appl. No.: 18/390,026

(22) Filed: Dec. 20, 2023

(30) Foreign Application Priority Data
Mar. 29, 2023 (KR) 10-2023-0041404

(51) Int. Cl. H01L 21/762; H01L 21/306; H01L 21/308; H01L 21/768

(52) U.S. Cl. CPC H01L 21/762; H01L 21/30625; H01L 21/3081; H01L 21/3086; H01L 21/76831; H01L 21/76832

(57) ABSTRACT

A method of fabricating a semiconductor device includes forming, in a semiconductor substrate, a device isolation trench defining active regions, forming a first liner dielectric layer covering a top surface of the semiconductor substrate and an inner wall of the device isolation trench, forming a second liner dielectric layer covering the first liner dielectric layer, forming a buried dielectric layer filling the device isolation trench, performing a polishing process on the second liner dielectric layer and the buried dielectric layer to form a device isolation structure, forming a mask pattern running across the active regions, and partially patterning the active regions and the device isolation structure to form gate trenches. After the polishing process, the first liner dielectric layer, the second liner dielectric layer, and the buried dielectric layer have their top surfaces formed by the polishing process coplanar with each other.

### CROSS-REFERENCE TO RELATED APPLICATION

This U.S. nonprovisional application claims priority under 35 U.S.C § 119 to Korean Patent Application No. 10-2023-0041404 filed on Mar. 29, 2023 in the Korean Intellectual Property Office, the disclosure of which is hereby incorporated by reference in its entirety.

### BACKGROUND

The present inventive concepts relate to a method of fabricating a semiconductor device and a semiconductor device fabricated by the same, and more particularly, to a method of fabricating a semiconductor device with improved reliability and a semiconductor device fabricated by the same.

Semiconductor devices have an important role in the electronic industry because of their small size, multi-functionality, and/or low fabrication cost. Semiconductor devices have become increasingly integrated with the development of the electronic industry. Line widths of patterns of semiconductor devices are being reduced for high integration thereof. However, new exposure techniques and/or expensive exposure techniques are required for fineness of the patterns such that it is difficult to highly integrate semiconductor devices. Various studies have thus recently been conducted for new integration techniques.

### SUMMARY

Some embodiments of the present inventive concepts provide a method of fabricating a semiconductor device with less occurrence of failure and a semiconductor device fabricated by the same.

Some embodiments of the present inventive concepts provide a method of fabricating a semiconductor device with improved structural stability and a semiconductor device fabricated by the same.

Some embodiments of the present inventive concepts provide a method of fabricating a semiconductor device with improved electrical properties and a semiconductor device fabricated by the same.

According to some embodiments of the present inventive concepts, a method of fabricating a semiconductor device may include: forming, in a semiconductor substrate, a device isolation trench that defines active regions; forming a first liner dielectric layer that conformally covers a top surface of the semiconductor substrate and an inner wall of the device isolation trench; forming a second liner dielectric layer that conformally covers the first liner dielectric layer; forming, on the semiconductor substrate, a buried dielectric layer that fills the device isolation trench; performing a polishing process on the second liner dielectric layer and the buried dielectric layer to form a device isolation structure; forming, on the semiconductor substrate, a mask pattern that runs across the active regions; and using the mask pattern to pattern portions of the active regions and portions of the device isolation structure to form gate trenches. After the polishing process, a top surface of the first liner dielectric layer, a top surface of the second liner dielectric layer, and a top surface of the buried dielectric layer formed by the polishing process may be coplanar with each other.

According to some embodiments of the present inventive concepts, a method of fabricating a semiconductor device may include: forming, in a semiconductor substrate, a device isolation trench that defines active regions; forming a first liner dielectric layer that conformally covers a top surface of the semiconductor substrate and an inner wall of the device isolation trench; forming a second liner dielectric layer that conformally covers the first liner dielectric layer; forming, on the semiconductor substrate, a buried dielectric layer that fills the device isolation trench; performing a polishing process on the second liner dielectric layer and the buried dielectric layer to form a device isolation structure, wherein the polishing process continues until a top surface of the first liner dielectric layer is exposed; forming a first mask pattern on the semiconductor substrate and a second mask pattern on the first mask pattern, wherein the same pattern is formed in the first mask pattern as in the second mask pattern; performing a first etching process on the active regions and the device isolation structure by using the second mask pattern; removing the second mask pattern; and performing a second etching process on the active regions and the device isolation structure by using the first mask pattern. After the polishing process, the top surface of the first liner dielectric layer and a top surface of the second liner dielectric layer may be at the same vertical level. The first and second etching processes may be performed such that portions of the active regions and portions of the device isolation structure may be patterned to form gate trenches.

According to some embodiments of the present inventive concepts, a method of fabricating a semiconductor device may include: forming, in a semiconductor substrate, a device isolation trench that defines active regions; forming a first liner dielectric layer that conformally covers a top surface of the semiconductor substrate and an inner wall of the device isolation trench; forming a second liner dielectric layer that conformally covers the first liner dielectric layer; forming, on the semiconductor substrate, a buried dielectric layer that fills the device isolation trench; performing a polishing process on the second liner dielectric layer and the buried dielectric layer to form a device isolation structure, wherein the polishing process continues until a top surface of the second liner dielectric layer and a top surface of the first liner dielectric layer are located at the same vertical level; forming, on the semiconductor substrate, a mask pattern that runs across the active regions; and patterning portions of the active regions and portions of the device isolation structure to form gate trenches by using the mask pattern. The gate trenches may run in a first direction across the active regions on the semiconductor substrate. A width in a second direction of the gate trenches may be uniform along the first direction. The second direction may be orthogonal to the first direction.

### BRIEF DESCRIPTION OF DRAWINGS

FIG. 1 illustrates a plan view showing a semiconductor device according to some embodiments of the present inventive concepts.

FIG. 2A illustrates a cross-sectional view taken along line A-A′ of FIG. 1.

FIG. 2B illustrates a cross-sectional view taken along lines B-B′ and C-C′ of FIG. 1.

FIG. 2C illustrates a cross-sectional view taken along lines D-D′ and E-E′ of FIG. 1.

FIG. 3 illustrates an enlarged view showing section P of FIG. 2A.

FIGS. 4 to 6, 7A to 10A, 11, and 12 illustrate cross-sectional views showing a method of fabricating a semiconductor device according to some embodiments of the present inventive concepts.

FIGS. 7B to 10B illustrate enlarged views showing section P of FIGS. 7A to 10A, respectively.

FIGS. 13A to 16A illustrate cross-sectional views showing a method of fabricating a semiconductor device according to a comparative example.

FIGS. 13B to 16B illustrate enlarged views showing section P of FIGS. 13A to 16A, respectively.

### DETAILED DESCRIPTION OF EMBODIMENTS

The following will now describe a semiconductor device according to the present inventive concepts with reference to accompanying drawings.

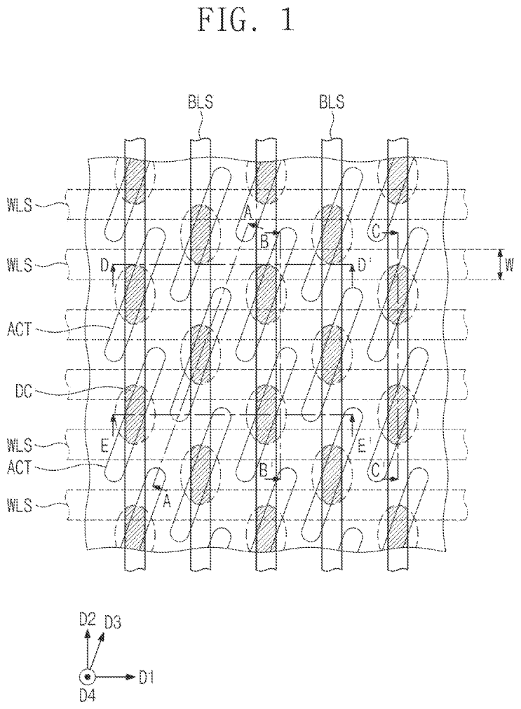

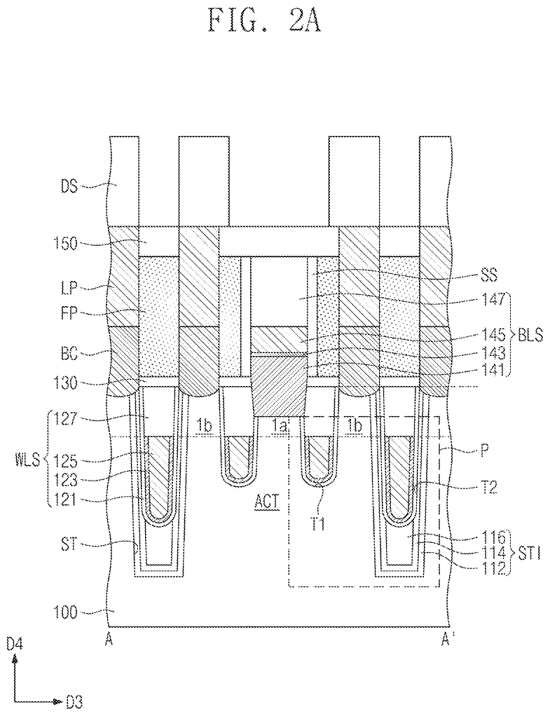

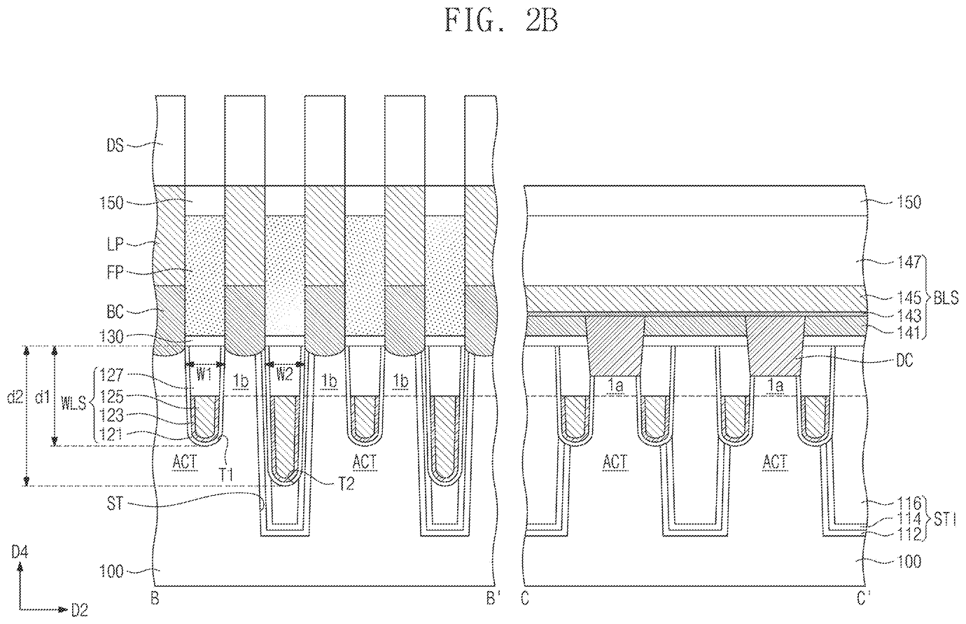

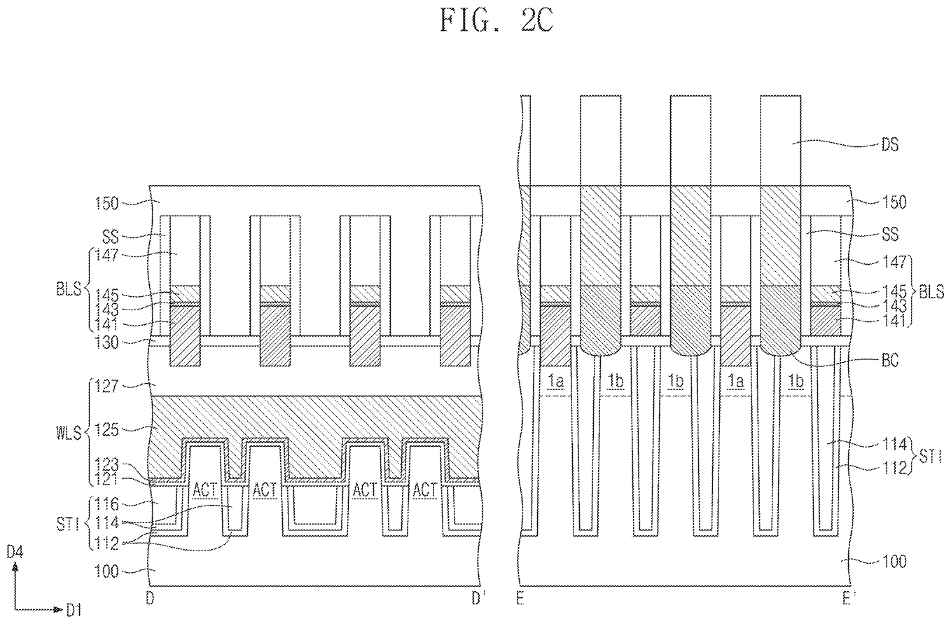

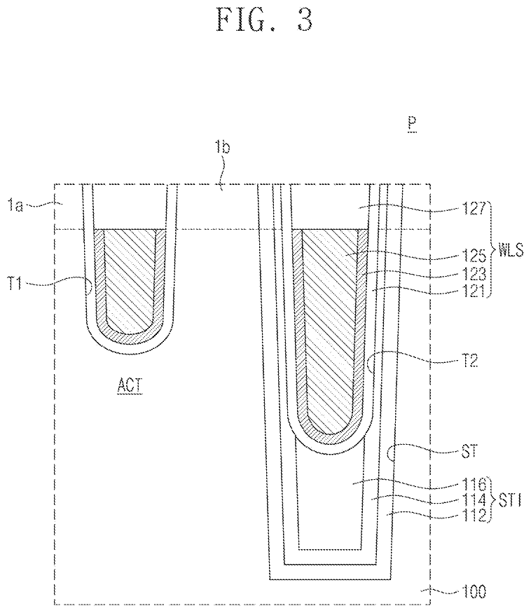

FIG. 1 illustrates a plan view showing a semiconductor device according to some embodiments of the present inventive concepts. FIG. 2A illustrates a cross-sectional view taken along line A-A′ of FIG. 1. FIG. 2B illustrates a cross-sectional view taken along lines B-B′ and C-C′ of FIG. 1. FIG. 2C illustrates a cross-sectional view taken along lines D-D′ and E-E′ of FIG. 1. FIG. 3 illustrates an enlarged view showing section P of FIG. 2A.

Referring to FIGS. 1, 2A, 2B, and 2C, a semiconductor substrate 100 may be provided which has a device isolation trench ST that defines active regions ACT.

The semiconductor substrate 100 may include a semiconductor material. For example, the semiconductor substrate 100 may be or include one or more of a silicon (Si) substrate, a germanium (Ge) substrate, and a silicon-germanium (SiGe) substrate.

The active regions ACT may each have a rectangular (or bar) shape when viewed in a plan view. The active regions ACT may be two-dimensionally arranged along a first direction D1 and a second direction D2. The first direction D1 and the second direction D2 may intersect each other. For example, the first direction D1 and the second direction D2 may be orthogonal to each other. The active regions ACT may be arranged in a zigzag shape when viewed in a plan view, and may each have a major axis extending in a third direction D3 oblique to the first direction DI and the second direction D2.

The device isolation trench ST may include a first part that has a first width between the active regions ACT that are adjacent to each other in the first direction D1 (see, e.g., FIG. 2C), and may also include a second part that has a second width in the third direction D3 oblique to the first and second directions D1 and D2 (see, e.g., FIG. 2A). The second width may be greater than the first width.

Referring further to FIG. 3, a device isolation structure STI may be disposed in the device isolation trench ST. For example, the device isolation structure STI may include a first liner dielectric pattern 112, a second liner dielectric pattern 114, and a buried dielectric pattern 116.

The first liner dielectric pattern 112 may be in contact with an inner wall of the device isolation trench ST. It will be understood that when an element is referred to as “contacting” or “in contact with” another element (or using any form of the word “contact”), there are no intervening elements present at the point of contact. The first liner dielectric pattern 112 may directly cover a bottom surface of the device isolation trench ST. The first liner dielectric pattern 112 may have a substantially uniform thickness. For example, the first liner dielectric pattern 112 may conformally cover the inner wall and the bottom surface of the device isolation trench ST. According to some embodiments, the first liner dielectric pattern 112 may have a spacer shape disposed on the inner wall of the device isolation trench ST. The first liner dielectric pattern 112 may not cover the bottom surface of the device isolation trench ST. The following description will focus on the embodiment of FIG. 3. The first liner dielectric pattern 112 may have a thickness of about 50 Å to about 150 Å. The first liner dielectric pattern 112 may be formed of or include a first dielectric material. For example, the first dielectric material may include silicon oxide (SiO).

The second liner dielectric pattern 114 may have a uniform thickness to cover the inner wall of the device isolation trench ST in which the first liner dielectric pattern 112 is formed. For example, the first liner dielectric pattern 112 and the second liner dielectric pattern 114 may constitute a dielectric layer that conformally covers the inner wall and the bottom surface of the device isolation trench ST, and the dielectric layer may include the first liner dielectric pattern 112 and the second liner dielectric pattern 114 that are sequentially stacked. In some embodiments, when the first liner dielectric pattern 112 does not cover the bottom surface of the device isolation trench ST, the second liner dielectric pattern 114 may be in contact with the bottom surface of the device isolation trench ST. The following description will focus on the embodiment of FIG. 3. The second liner dielectric pattern 114 may have a thickness of about 50 Å to about 150 Å. The second liner dielectric pattern 114 may be formed of or include a second dielectric material. The second dielectric material may be different from the first dielectric material. The second dielectric material may have an etch selectivity with respect to the first dielectric material. For example, the second dielectric material may include silicon nitride (SiN).

Referring back to FIGS. 1, 2A, 2B, and 2C, as shown in FIG. 2C, the second liner dielectric pattern 114 may completely fill the device isolation trench ST in which the first liner dielectric pattern 112 is formed in an area having a small distance between the active regions ACT. For example, the device isolation trench ST may be fully filled with the second liner dielectric pattern 114 between some of the active regions ACT that are adjacent to each other in the direction D1.

The buried dielectric pattern 116 may be disposed in a gap defined by the second liner dielectric pattern 114. The buried dielectric pattern 116 may completely fill the device isolation trench ST in which are formed the first liner dielectric pattern 112 and the second liner dielectric pattern 114. The buried dielectric pattern 116 may have a top surface located at substantially the same level as that of a top surface of the semiconductor substrate 100. The buried dielectric pattern 116 may be formed of or include at least one selected from silicon oxide (SiO), silicon oxynitride (SiON), and silicon nitride (SiN). For example, the buried dielectric pattern 116 may include silicon oxide (SiO).

The semiconductor substrate 100 may be provided with gate trenches T1 and T2 therein (see, e.g., FIGS. 2A, 2B, and 3). The gate trenches T1 and T2 may extend parallel to each other along the first direction D1, while running across the active regions ACT and the device isolation structure STI.

The gate trenches T1 and T2 may have their bottom surfaces whose depths are different depending on materials thereunder. The gate trenches T1 and T2 may include a first trench T1 having a first depth d1 in the active regions ACT and second trenches T2 each having a second depth d2 in the device isolation structure STI. The second depth d2 may be greater the first depth d1. For example, the bottom surface of the second trench T2 may be located at a lower level than that of the bottom surface of the first trench T1. As shown in FIG. 3, the first trench T1 may be located at a first level from the top surface of the semiconductor substrate 100, and the second trench T2 may be located at a second level lower than the first level. A width in the second direction D2 of each of the gate trenches T1 and T2 may be uniform along the first direction D1. The width in the second direction D2 of the first trench T1 may be the same as the width in the second direction D2 of the second trench T2.

Word-line structures WLS may be disposed on and/or in the gate trenches T1 and T2. One active region ACT may intersect a pair of word-line structures WLS. A portion of each word-line structure WLS may be provided in the first trenches T1, and another portion of each word-line structure WLS may be provided in the second trenches T2.

Each of the word-line structures WLS may include a gate dielectric pattern 121, a gate barrier metal pattern 123, a gate conductive pattern 125, and a gate capping pattern 127.

The gate dielectric pattern 121 may have a uniform thickness to cover inner walls of the first and second trenches T1 and T2. The gate dielectric pattern 121 may be formed of or include, for example, at least one selected from silicon oxide (SiO), silicon nitride (SiN), silicon oxynitride (SiON), and high-k dielectrics.

The gate barrier metal pattern 123 may conformally cover the gate dielectric pattern 121 in the first and second trenches T1 and T2. The gate barrier metal pattern 123 may be interposed between the gate dielectric pattern 121 and the gate conductive pattern 125.

The gate barrier metal pattern 123 may be formed of or include metal nitride. For example, the gate barrier metal pattern 123 may include at least one selected from titanium nitride (TiN), tungsten nitride (WN), and any combination thereof, but the present inventive concepts are not limited thereto.

A top surface of the gate conductive pattern 125 may be positioned lower than the top surface of the semiconductor substrate 100. In the first and second trenches T1 and T2, the top surfaces of the gate conductive patterns 125 may be located at substantially the same level.

The gate conductive pattern 125 may be formed of or include a conductive material. The gate conductive pattern 125 may include, for example, at least one selected from titanium (Ti), tantalum (Ta), tungsten (W), aluminum (Al), cobalt (Co), any other metal, and a combination thereof. Additionally or alternatively, the gate conductive pattern 125 may include polysilicon or silicon-germanium (SiGe) other than metal.

The gate capping pattern 127 may be disposed on the gate barrier metal pattern 123 and the gate conductive pattern 125. A top surface of the gate capping pattern 127 may be substantially coplanar with that of the semiconductor substrate 100 and that of the device isolation structure STI. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. For example, “planarization,” “co-planar,” “planar,” etc., as used herein refer to structures (e.g., surfaces) that need not be perfectly geometrically planar, but may include acceptable variances that may result from standard manufacturing processes. The gate capping pattern 127 may be formed of or include, for example, silicon nitride (SiN) or silicon oxynitride (SiON).

The word-line structures WLS may each have a height that is greater in the second trench T2 than in the first trench T1. Each of the word-line structures WLS may include a first gate structure provided in the first trench T1 and a second gate structure provided in the second trench T2.

The word-line structures WLS may each have a width in the second direction D2, and the width may be uniform along the first direction D1. For example, a first width W1 in the second direction D2 of the first gate structure may be substantially the same as a second width W2 in the second direction D2 of the second gate structure. In addition, the first width W1 of the first gate structure may be uniform along the first direction D1, and the second width W2 of the second gate structure may be uniform along the first direction D1.

According to some embodiments of the present inventive concepts, as the gate trenches T1 and T2 and the word-line structures WLS have uniform widths along the first direction D1, the word-line structures WLS may have electrical resistances that are uniform irrespective of position in the first direction D1. Therefore, a semiconductor device may be provided with uniform electrical signals applied to transistors therein, and may have improved electrical properties.

First and second impurity regions 1a and 1b may be formed in the active region ACT on opposite sides of each of the word-line structures WLS. The first impurity region 1a and the second impurity regions 1b may correspond to a source impurity region and drain impurity regions, respectively. The first and second impurity regions 1a and 1b may have their bottom surfaces that are positioned at a depth from a top surface of the active region ACT. The first impurity region 1a may be disposed in the active region ACT between the word-line structures WLS, and the second impurity regions 1b may be spaced apart from the first impurity region 1a and disposed on end portions of each active region ACT. The first and second impurity regions 1a and 1b may be doped with dopants having a conductivity type opposite to that of the semiconductor substrate 100.

A first interlayer dielectric layer 130 may be disposed on the semiconductor substrate 100. The first interlayer dielectric layer 130 may be formed of or include a plurality of dielectric layers. For example, the first interlayer dielectric layer 130 may include a silicon oxide layer (SiO) and a silicon nitride layer (SiN) that are sequentially stacked. Alternatively, the first interlayer dielectric layer 130 may be formed of a single layer. The first interlayer dielectric layer 130 may cover end portions of two neighboring active regions ACT and a portion of the device isolation structure STI between the end portions (see, e.g., FIG. 2C).

The first interlayer dielectric layer 130 may be provided thereon with bit-line structures BLS that extend lengthwise in the second direction D2 and run across the word-line structures WLS. The bit-line structures BLS may be correspondingly disposed on the first impurity regions 1a. According to an embodiment, the bit-line structures BLS may each be formed of or include a polysilicon pattern 141, a silicide pattern 143, a metal pattern 145, and a hardmask pattern 147 that are sequentially stacked. The first interlayer dielectric layer 130 may be interposed between the polysilicon pattern 141 and the semiconductor substrate 100, and the polysilicon pattern 141 may have a portion (referred to hereinafter as a bit-line contact pattern DC, see FIG. 2B) in contact with the first impurity region 1a. The silicide pattern 143 may be formed of or include, for example, at least one selected from titanium silicide (TiSi₂), cobalt silicide (CoSi₂), and nickel silicide (NiSi). The metal pattern 145 may be formed of or include, for example, one or more of conductive metal nitride (titanium nitride (TiN), tantalum nitride (TaN), etc.) and metal (tungsten (W), titanium (Ti), tantalum (Ta), etc.). The hardmask pattern 147 may be formed of or include a dielectric material, such as silicon nitride (SiN).

A bottom surface of the bit-line contact pattern DC may be positioned lower than the top surface of the semiconductor substrate 100 and lower than top surfaces of the word-line structures WLS. For example, the bit-line contact pattern DC may be locally disposed in a recess that is formed in the semiconductor substrate 100 and that exposes the first impurity region 1a. The recess may have an oval shape, and a minimum width of the recess may be greater than a width of each of the bit-line structures BLS.

Bit-line spacers SS may be disposed on opposite sidewalls of each of the bit-line structures BLS. The bit-line spacers SS may extend in the second direction D2 along the sidewalls of the bit-line structures BLS. The bit-line spacers SS may be disposed between the sidewalls of the bit-line structures BLS and buried contact patterns BC and between the sidewalls of the bit-line structures BLS and fence patterns FP.

The fence patterns FP may be disposed spaced apart from each other in the second direction D2 between the bit-line structures BLS. The fence patterns FP may be disposed between the buried contact patterns BC that are adjacent to each other in the second direction D2. The fence patterns FP may overlap the word-line structures WLS when viewed in a plan view, and may be disposed on the gate capping pattern 127. The fence patterns FP may have their top surfaces located at substantially the same level as that of top surfaces of the bit-line structures BLS (see, e.g., FIG. 2B). The fence patterns FP may be formed of or include a dielectric material, such as silicon nitride (SiN).

The buried contact patterns BC may be disposed between a pair of neighboring bit-line structures BLS (see, e.g., FIG. 2C). The buried contact patterns BC may be formed of or include, for example, metal or impurity-doped polysilicon. The buried contact patterns BC may be in contact with corresponding second impurity regions 1b. When viewed in a plan view, the buried contact patterns BC may be correspondingly disposed between the word-line structures WLS and between the bit-line structures BLS.

The buried contact patterns BC may be two-dimensionally disposed spaced apart from each other. For example, the buried contact patterns BC arranged along the first direction D1 may be spaced apart from each other across the bit-line structures BLS. The buried contact patterns BC arranged along the second direction D2 may be spaced apart from each other across the fence patterns FP. The buried contact patterns BC may fill spaces defined by the bit-line structures BLS that are adjacent to each other in the first direction D1 and by the fence patterns FP that are adjacent to each other in the second direction D2. The buried contact patterns BC may have their top surfaces located at a lower level than that of the top surfaces of the fence patterns FP and that of the top surfaces of the bit-line structures BLS. The top surfaces of the buried contact patterns BC may be positioned higher than the top surface of the gate conductive pattern 125 of the word-line structure WLS.

The buried contact patterns BC may have their bottom surfaces positioned lower than the top surface of the semiconductor substrate 100 and higher than the bottom surface of the bit-line contact pattern DC. In addition, the buried contact patterns BC may be spaced apart from the bit-line contact pattern DC.

Landing pads LP may be correspondingly disposed on the buried contact patterns BC. The landing pads LP may be electrically connected to corresponding buried contact patterns BC.

A top surface of the landing pad LP may be positioned higher than the top surfaces of the bit-line structures BLS, and a bottom surface of the landing pad LP may be positioned lower than the top surfaces of the bit-line structures BLS. For example, the bottom surface of the landing pad LP may be positioned higher than the top surface of the gate barrier metal pattern 123 of the word-line structure WLS.

According to some embodiments, when viewed in a plan view, an upper portion of the landing pad LP may have a circular shape, an oval shape, a rhombic shape with rounded corners, a trapezoidal shape with rounded corners, or a tetragonal shape with rounded corners. Each of the landing pads LP may be formed of or include a contact silicide pattern, a barrier metal pattern, and a metal pattern.

The contact silicide pattern may cover the top surface of the buried contact pattern BC. The contact silicide pattern may be formed of or include, for example, titanium silicide (TiSi₂), cobalt silicide (CoSi₂), nickel silicide (NiSi), tungsten silicide (WSi₂), platinum silicide (PtSi), or molybdenum silicide (MoSi₂). Alternatively, the contact silicide pattern may be omitted. The landing pad LP may be formed of or include, for example, one or more of conductive metal nitride (titanium nitride (TiN), tantalum nitride (TaN), tungsten nitride (WN), etc.) and metal (tungsten (W), titanium (Ti), tantalum (Ta), etc.).

According to some embodiments, data storage elements DS may be correspondingly disposed on the landing pads LP. The data storage elements DS may be correspondingly electrically connected to the second impurity regions 1b through the landing pads LP and the buried contact patterns BC. The data storage elements DS may be correspondingly misaligned and in partial contact with the landing pads LP. For example, when viewed in a plan view, the data storage elements DS may be disposed in a honeycomb shape or a zigzag shape.

According to some embodiments, the data storage elements DS may be a capacitor, and the capacitor may be formed of or include bottom electrodes, top electrodes, and a dielectric layer between the top and bottom electrodes. Alternatively, the data storage elements DS may be a variable resistance pattern whose two resistance states are switched by an electrical pulse applied to a memory element. For example, the data storage elements DS may include a phase-change material whose crystalline state is changed based on an amount of current, perovskite compounds, transition metal oxide, magnetic materials, ferromagnetic materials, or antiferromagnetic materials.

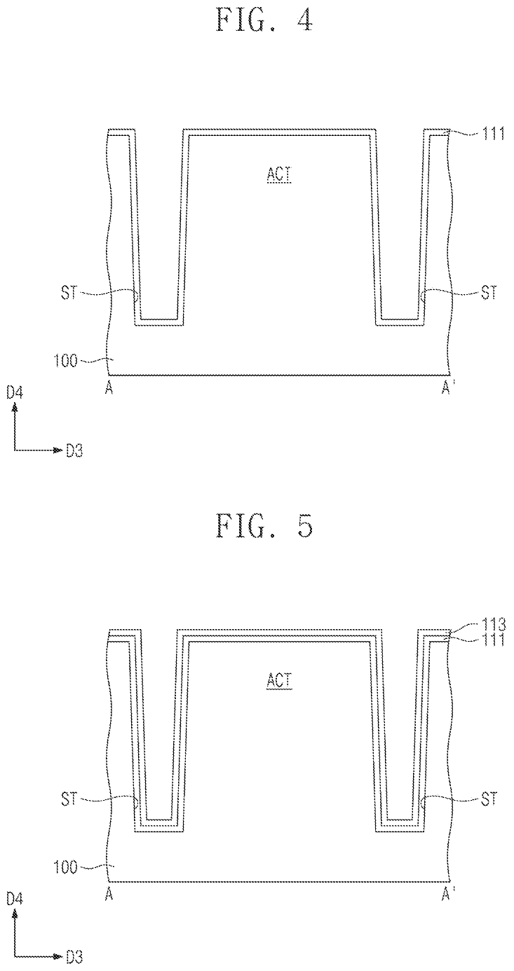

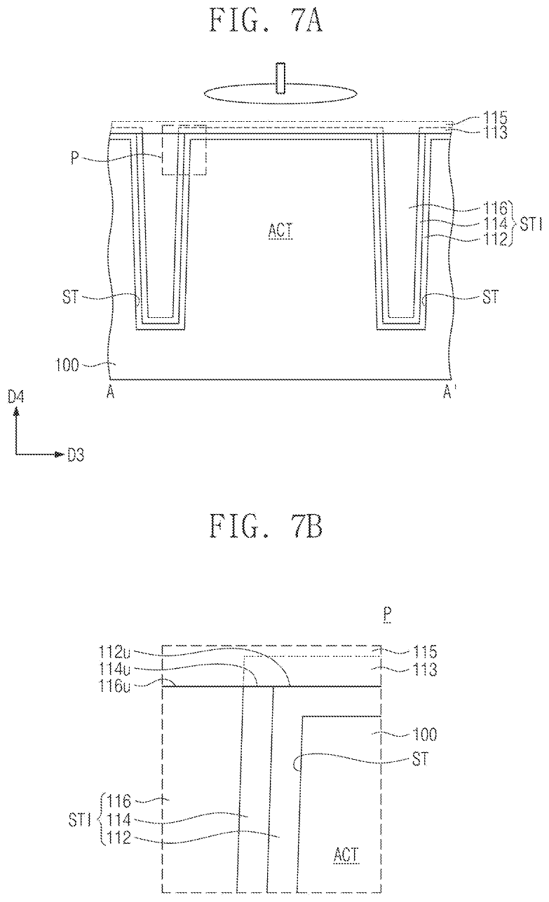

FIGS. 4-6, 7A-10A, 11, 12, and 13A-16A illustrate cross-sectional views showing a method of fabricating a semiconductor device according to some embodiments of the present inventive concepts. FIGS. 7B to 10B and 13B-16B illustrate enlarged views showing section P of FIGS. 7A to 10A and 13A-16A, respectively.

Referring to FIGS. 1 and 4, a device isolation trench ST defining active regions ACT may be formed in a semiconductor substrate 100. The semiconductor substrate 100 may be formed of or include one or more of a silicon (Si) substrate, a germanium (Ge) substrate, and a silicon-germanium (SiGe) substrate.

The device isolation trench ST may be formed by forming a mask pattern (not shown) on the semiconductor substrate 100 and using the mask pattern as an etching mask to anisotropically etch the semiconductor substrate 100 to have a certain depth.

The device isolation trench ST may have a first width between the active regions ACT that are adjacent to each other in a first direction D1 and a second width, which is greater than the first width, between the active regions ACT that are adjacent to each other in a third direction D3.

The active regions ACT may each have a rectangular (or bar) shape that extends in the third direction D3. The active regions ACT may be two-dimensionally arranged in the first direction D1 and a second direction D2 that intersects (or is orthogonal to) the first direction D1. The active regions ACT may be arranged in a zigzag shape when viewed in a plan view, and may each have a major axis in a direction (or the third direction D3) oblique to the first direction D1 and the second direction D2.

After the formation of the device isolation trench ST, a first liner dielectric layer 111 may be formed to conformally cover an inner wall of the device isolation trench ST. The first liner dielectric layer 111 may be formed by using a thermal oxidation process or a deposition process. The first liner dielectric layer 111 may be formed by using a layer-formation technique, such as chemical vapor deposition (CVD) or atomic layer deposition (ALD), having superior step coverage properties. When a deposition process is performed to form the first liner dielectric layer 111, the first liner dielectric layer 111 may be formed to have a uniform thickness on a bottom surface and an upper sidewall of the device isolation trench ST. When a thermal oxidation process is performed, the first liner dielectric layer 111 may be selectively formed on a surface of the semiconductor substrate 100. The first liner dielectric layer 111 may be formed of or include, for example, silicon oxide (SiO).

Referring to FIGS. 1 and 5, a second liner dielectric layer 113 may be formed on the first liner dielectric layer 111. The second liner dielectric layer 113 may be formed by using a thermal oxidation process or a deposition process. The second liner dielectric layer 113 may be formed by using a layer-formation technique, such as chemical vapor deposition (CVD) or atomic layer deposition (ALD), having superior step coverage properties. When a deposition process is performed to form the second liner dielectric layer 113, the second liner dielectric layer 113 may be formed to have a uniform thickness on a surface of the first liner dielectric layer 111. When a thermal oxidation process is performed, the second liner dielectric layer 113 may be selectively formed on a surface of the first liner dielectric layer 111. The second liner dielectric layer 113 may be formed of or include a material having an etch selectivity with respect to the first liner dielectric layer 111. The second liner dielectric layer 113 may be formed of, for example, silicon nitride (SiN).

In addition, as shown in FIG. 2C, the second liner dielectric layer 113 may completely fill the device isolation trench ST between the active regions ACT that are adjacent to each other in the first direction D1. The second liner dielectric layer 113 of FIG. 5 may correspond, e.g., to the second liner dielectric pattern 114 of FIG. 2C.

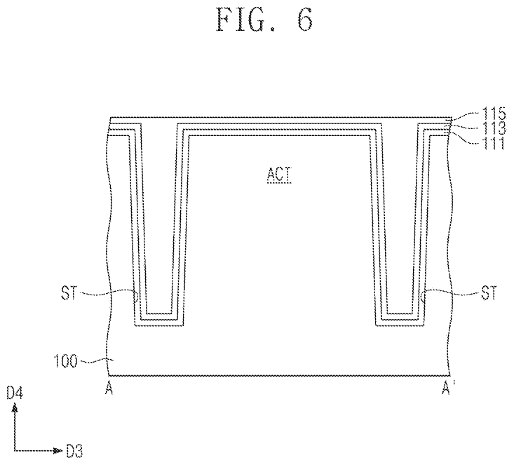

Referring to FIGS. 1 and 6, a buried dielectric layer 115 may be formed to fill the device isolation trench ST in which the first and second liner dielectric layers 111 and 113 are formed. The buried dielectric layer 115 may be formed of or include, for example, one or more of silicon oxide (SiO), silicon nitride (SiN), and silicon oxynitride (SiON).

The buried dielectric layer 115 may be formed by using a layer-formation technique, such as chemical vapor deposition (CVD) or atomic layer deposition (ALD), having superior step coverage properties. In this case, the buried dielectric layer 115 may completely fill the device isolation trench ST in which the first and second liner dielectric layers 111 and 113 are formed. In some embodiments, the buried dielectric layer 115 may fill the device isolation trench ST between the active regions ACT that are adjacent to each other in the third direction D3.

Referring to FIGS. 1, 7A, and 7B, the second liner dielectric layer 113 and the buried dielectric layer 115 may undergo a planarization process to expose a top surface of the first liner dielectric layer 111. Therefore, the second liner dielectric layer 113 and the buried dielectric layer 115 may be partially removed to expose a top surface 112u of the first liner dielectric layer 111 (or of a first liner dielectric pattern 112 formed by patterning the first liner dielectric layer 111). Thus, a device isolation structure STI may be formed to include a first liner dielectric pattern 112, a second liner dielectric pattern 114, and a buried dielectric pattern 116 in the device isolation trench ST. The first and second liner dielectric patterns 112 and 114 may be formed to have respective top surfaces 112u and 114u located at the same vertical level. For example, a top surface of the device isolation structure STI may be coplanar with the top surface 112u of the first liner dielectric layer 111. The planarization process may include a chemical mechanical polishing (CMP) process.

According to some embodiments, the planarization process may continue until a top surface of the semiconductor substrate 100 is exposed. Therefore, the first liner dielectric layer 111, the second liner dielectric layer 113, and the buried dielectric layer 115 may be partially removed to expose the top surface of the semiconductor substrate 100. Thus, a device isolation structure STI may be formed in the device isolation trench ST. A first liner dielectric pattern 112, a second liner dielectric pattern 114, and a buried dielectric pattern 116 may be formed to respectively have a top surface 112u, a top surface 114u, and a top surface 116u that are located at the same vertical level. For example, a top surface of the device isolation structure STI may be coplanar with the top surface of the semiconductor substrate 100. In other words, a first distance between a bottom surface of the semiconductor substrate 100 and the top surface 112u of the first liner dielectric pattern 112 may be substantially the same as a second distance between the bottom surface of the semiconductor substrate 100 and the top surface 114u of the second liner dielectric pattern 114 and a third distance between the bottom surface of the semiconductor substrate 100 and the top surface 116u of the buried dielectric pattern 116.

According to some embodiments of the present inventive concepts, a planarization process may be performed either on both of the second liner dielectric layer 113 and the buried dielectric layer 115 that include different materials from each other or on all of the first liner dielectric layer 111, the second liner dielectric layer 113, and the buried dielectric layer 115 that include different materials from each other. Even though the first liner dielectric layer 111, the second liner dielectric layer 113, and the buried dielectric layer 115 have different etch rates with respect to slurry (e.g., etchant) used in the planarization process, a chemical mechanical polishing process including physical polishing may be performed as the planarization process, and thus after the planarization process, the first liner dielectric pattern 112, the second liner dielectric pattern 114, and the buried dielectric pattern 116 may have their respective top surfaces 112u, 114u, and 116u that are substantially flat and coplanar with each other. Accordingly, it may be possible to suppress failure occurring due to protrusion or depression of the top surface of either the semiconductor substrate 100 or the device isolation structure STI. As a result, there may be provided a method of fabricating a semiconductor device with less occurrence of failure. This will be further discussed in detail below.

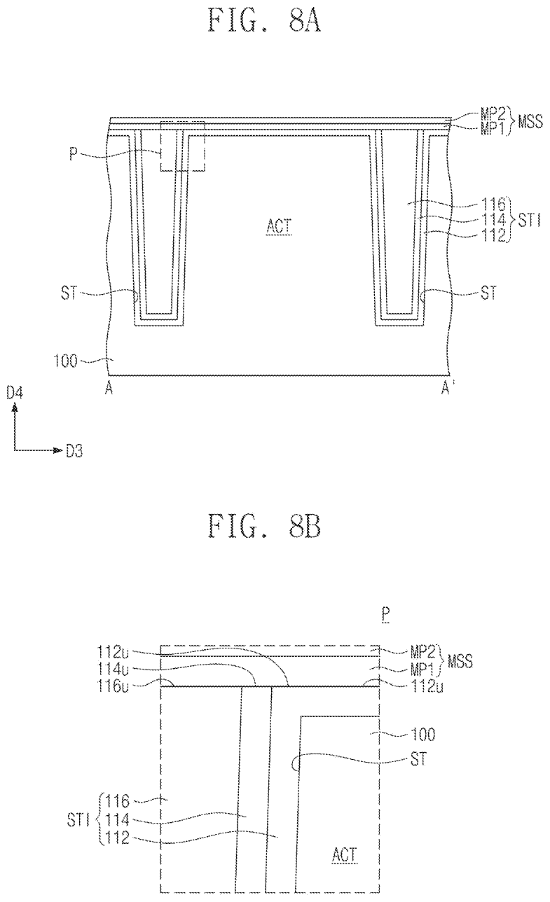

Referring to FIGS. 1, 8A, and 8B, a mask structure MSS may be formed on the semiconductor substrate 100. For example, a first mask pattern MP1 and a second mask pattern MP2 may be sequentially stacked on the semiconductor substrate 100. At the step of FIGS. 8A and 8B, each of the first mask pattern MP1 and the second mask pattern MP2 may be a deposition layer before the formation of a pattern, and may cover an entire surface of the semiconductor substrate 100, or an entirety of the top surface of the semiconductor substrate 100 and an entirety of the device isolation structure STI. The first mask pattern MP1 may be formed by a low-temperature atomic layer deposition (LT-ALD) process. The first mask pattern MP1 may be formed of or include silicon oxide (SiO). The present inventive concepts, however, are not limited thereto, and the first mask pattern MP1 may include a mask layer having an etch selectivity with respect to the second liner dielectric pattern 114 and the buried dielectric pattern 116. The second mask pattern MP2 may be formed by a chemical vapor deposition (CVD) process. The second mask pattern MP2 may be formed of or include an amorphous carbon layer (ACL). The first and second mask patterns MP1 and MP2 may each have a plate shape. On the top surface 114u of the second liner dielectric pattern 114, the first mask pattern MP1 and the second mask pattern MP2 may have their top surfaces that are substantially flat. In addition, the first mask pattern MP1 may have a thickness that is uniform irrespective of position, and likewise the second mask pattern MP2 may also have a thickness that is uniform irrespective of position.

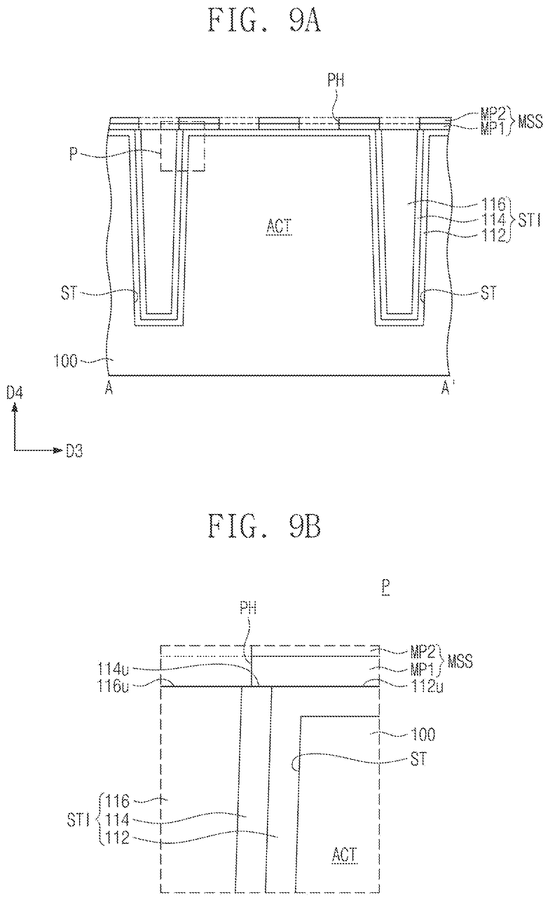

Referring to FIGS. 1, 9A, and 9B, pattern holes PH may be formed in the mask structure MSS. The pattern holes PH may define zones where gate trenches T1 and T2 are to be formed in a subsequent process. The pattern holes PH may penetrate the first mask pattern MP1 and the second mask pattern MP2 to expose the semiconductor substrate 100 or the device isolation structure STI.

According to some embodiments of the present inventive concepts, as the first and second mask patterns MP1 and MP2 have their thicknesses that are uniform irrespective of position, the pattern holes PH may be easily formed. For example, when the second mask pattern MP2 is patterned, an etching (or patterning) time required for complete penetration of the second mask pattern MP2 may be the same irrespective of position, and after the patterning process, a portion of the second mask pattern MP2 may not remain in the pattern holes PH. In addition, when the first mask pattern MP1 is patterned, an etching (or patterning) time required for complete penetration of the first mask pattern MP1 may be the same irrespective of position, and after the patterning process, a portion of the first mask pattern MP1 may not remain in the pattern holes PH. Thus, the pattern holes PH may have flat inner walls, and the width of the pattern hole PH may also be uniform irrespective of position from the top surface of the semiconductor substrate 100. In addition, the pattern holes PH may have therein no residue of either the first mask pattern MP1 or the second mask pattern MP2. The pattern holes PH may exactly expose the zones where gate trenches T1 and T2 are to be formed in a subsequent process, and the gate trenches T1 and T2 may be easily formed having required sizes or shapes.

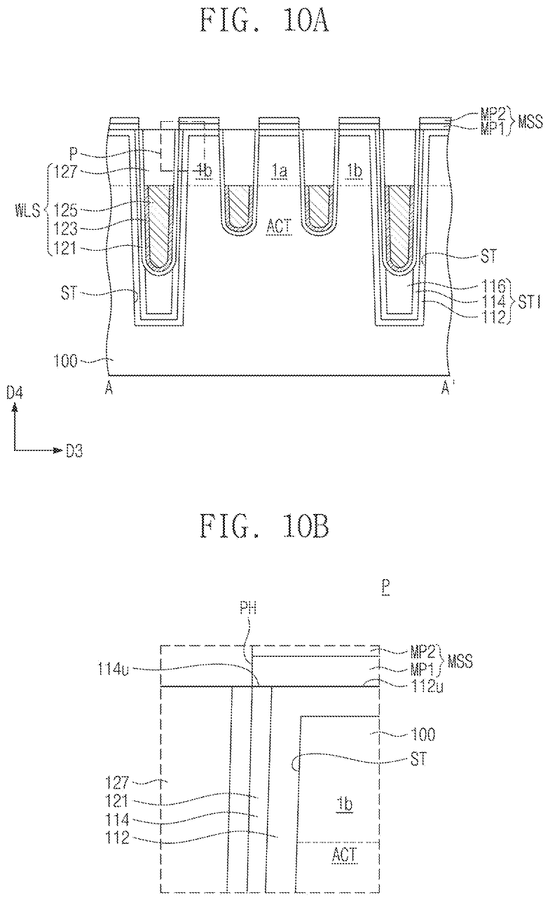

Referring to FIGS. 1, 10A, and 10B, gate trenches T1 and T2 may be formed in the semiconductor substrate 100. The gate trenches T1 and T2 may be formed by using the mask structure MSS to pattern portions of the active regions ACT and portions of the device isolation structure STI.

For example, the formation of the gate trenches T1 and T2 may include using the mask structure MSS as an etching mask to anisotropically etch the semiconductor substrate 100. In the anisotropic etching process, the device isolation structure STI and the active regions ACT may be partially etched. For example, the second mask pattern MP2 may be used to firstly etch the semiconductor substrate 100 (e.g., in a first etching process), the second mask pattern MP2 may be removed, the first mask pattern MP1 may be used to secondly etch the semiconductor substrate 100 (e.g., a second etching process), and then the first mask pattern MP1 may be removed.

In the anisotropic etching process, a difference in material may cause the first trenches T1 having a first depth to be formed on the active regions ACT and the second trenches T2 having a second depth, which is greater than the first depth, to be formed on the device isolation structure STI. The second trenches T2 may have bottom surfaces located at a lower level than that of a top surface of the first liner dielectric pattern 112. The gate trenches T1 and T2 may have widths each of which is less than a distance between active regions ACT that are adjacent to each other in the third direction D3 (or a width of the device isolation structure STI).

Word-line structures WLS may be formed on and/or in the gate trenches T1 and T2.

For example, after the gate trenches T1 and T2 are formed, a gate dielectric layer, a gate barrier metal layer, and a gate conductive layer may be sequentially formed in the gate trenches T1 and T2, and the gate barrier metal layer and the gate conductive layer may be etched to locally form a gate barrier metal pattern 123 and a gate conductive pattern 125 in the gate trenches T1 and T2. The gate dielectric layer may be deposited to have a uniform thickness on inner walls of the gate trenches T1 and T2.

On the gate barrier metal pattern 123 and the gate conductive pattern 125, a gate capping pattern 127 may be formed to fill the gate trenches T1 and T2.

After the formation of the word-line structures WLS, first and second impurity regions 1a and 1b may be formed in the active regions ACT on opposite sides of each of the word-line structures WLS. The first and second impurity regions 1a and 1b may be formed by performing an ion implantation process, and may have a conductivity type opposite to that of the active regions ACT.

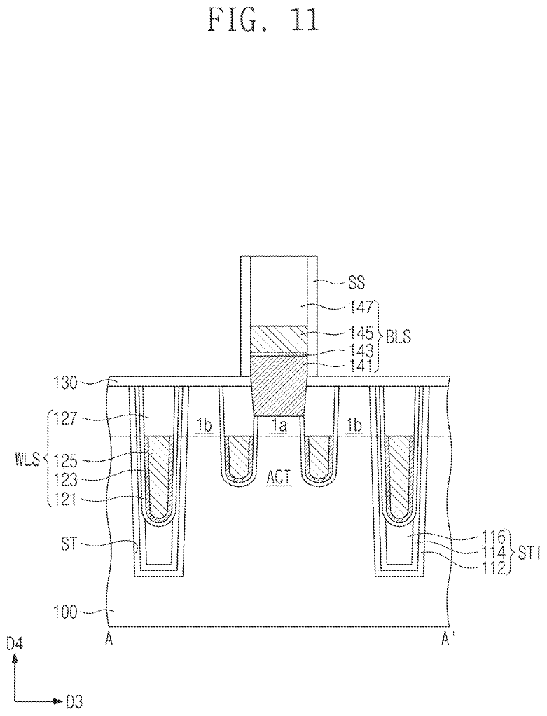

Referring to FIGS. 1 and 11, a first interlayer dielectric layer 130 may be formed on the entire surface of the semiconductor substrate 100. The first interlayer dielectric layer 130 may include a single dielectric layer or a plurality of dielectric layers. The first interlayer dielectric layer 130 may be formed of or include, for example, one or more of silicon oxide (SiO), silicon nitride (SiN), and silicon oxynitride (SiON).

The semiconductor substrate 100 and the first interlayer dielectric layer 130 may be patterned to form contact recesses each of which exposes a central portion of the active region ACT. In some embodiments, the contact recesses may each have an oval shape that has a major axis in the second direction D2. In addition, when viewed in a plan view, the contact recesses may be arranged in a zigzag or honeycomb shape. A portion of the device isolation structure STI may be etched by an etching process used for forming the contact recesses.

Bit-line structures BLS extending in the second direction D2 may be formed on the first interlayer dielectric layer 130 having the contact recesses.

The formation of the bit-line structures BLS may include forming on the first interlayer dielectric layer 130 a first conductive layer that fills the contact recesses, forming a second conductive layer on the first conductive layer, forming a hardmask layer on the second conductive layer, forming a bit-line mask pattern on the hardmask layer, and using the bit-line mask pattern to sequentially etch the first conductive layer, the second conductive layer, and the hardmask layer. The first conductive layer may be formed of or include an impurity-doped semiconductor layer such as a polysilicon layer, and the second conductive layer may be formed of or include a metal layer such as a tungsten (W) layer, an aluminum (Al) layer, a titanium (Ti) layer, or a tantalum (Ta) layer. In addition, a metal silicide layer may be formed between the first conductive layer and the second conductive layer.

As the bit-line structures BLS are formed as discussed above, the bit-line structures BLS may each include a polysilicon pattern 141, a silicide pattern 143, a metal pattern 145, and a hardmask pattern 147 that are sequentially stacked. A portion of the polysilicon pattern 141 may be locally formed in the contact recesses, and the portion of the polysilicon pattern 141 may constitute a bit-line contact pattern DC in contact with the first impurity region 1a.

Afterwards, bit-line spacers SS may be formed on sidewalls of the bit-line structures BLS. The bit-line spacers SS may extend in the second direction D2 along opposite sidewalls of the bit-line structures BLS. The bit-line spacers SS may be formed of or include a single layer or a multiple layer.

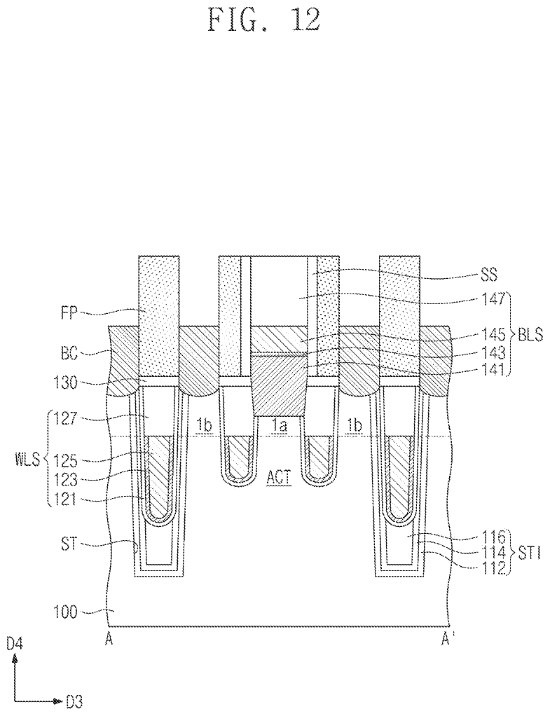

Referring to FIGS. 1 and 12, fence patterns FP may be formed on the word-line structures WLS between the bit-line structures BLS.

The fence patterns FP may be disposed spaced apart from each other in the second direction D2 between the bit-line structures BLS. The fence patterns FP may be formed of or include, for example, one or more of silicon oxide (SiO), silicon nitride (SiN), and silicon oxynitride (SiON).

After the formation of the fence patterns FP, contact holes may be formed to locally expose portions of the active regions ACT between the bit-line structures BLS. When viewed in a plan view, the contact holes may be defined by the bit-line structures BLS and the fence pattern FP. The contact holes may be formed by anisotropically etching a portion of the first interlayer dielectric layer 130, a portion of the semiconductor substrate 100, and a portion of the device isolation structure STI. The contact holes may have their bottom surfaces positioned lower than the top surface of the semiconductor substrate 100.

Buried contact patterns BC may be formed to fill the contact holes. The buried contact patterns BC may be in contact with the second impurity regions 1b on opposite sides of each of the bit-line structures BLS. The buried contact patterns BC may have their top surfaces positioned lower than top surfaces of the hardmask patterns 147 of the bit-line structures BLS and higher than the top surface of the semiconductor substrate 100.

The formation of the buried contact patterns BC may include depositing a conductive layer that fills the contact holes, planarizing the conductive layer to expose top surfaces of the bit-line structures BLS and the fence patterns FP, and recessing a top surface of the conductive layer.

Referring back to FIGS. 1, 2A, 2B, and 2C, landing pads LP may be formed which are correspondingly connected to the buried contact patterns BC.

The formation of the landing pads LP may include conformally depositing a barrier metal layer on the entire surface of the semiconductor substrate 100, forming on the barrier metal layer a metal layer that fills the a contact region, forming mask patterns (not shown) on the metal layer, and using the mask patterns as an etching mask to sequentially etch the metal layer and the barrier metal layer to form a pad recess. When the landing pads LP are formed, contact silicide patterns may be correspondingly formed between the landing pads LP and top surfaces of the buried contact patterns BC.

A second interlayer dielectric layer 150 may fill a space between upper portions of the landing pads LP.

Data storage elements DS may be correspondingly formed on the landing pads LP. The data storage element DS may be provided in various shapes. For example, the data storage element DS may be achieved as a capacitor, a variable resistor, or the like.

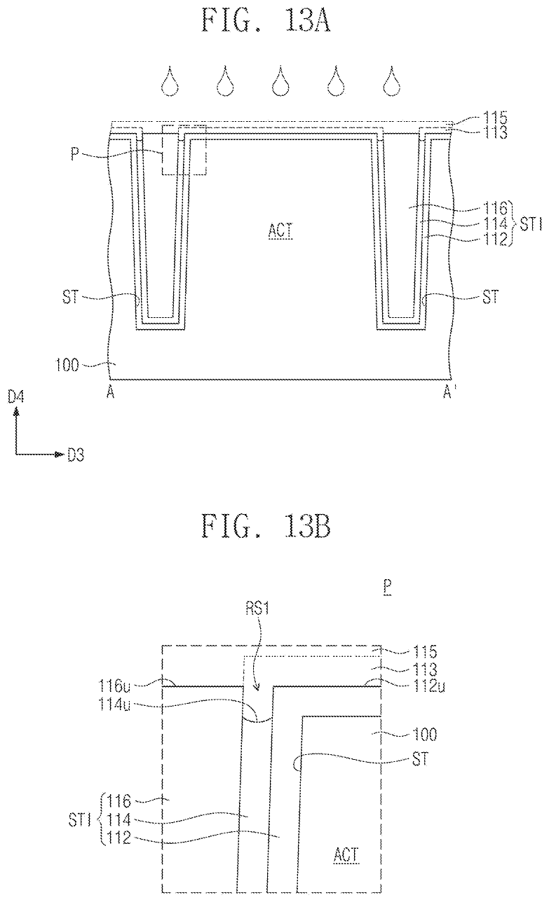

FIGS. 13A to 16A illustrate cross-sectional views showing a method of fabricating a semiconductor device according to a comparative example. FIGS. 13B to 16B illustrate enlarged views showing section P of FIGS. 13A to 16A, respectively. FIGS. 13A to 16A and 13B to 16B illustrate diagrams showing a method of fabricating a semiconductor device, and the following will focus on a difference from the method of fabricating a semiconductor device discussed with reference to FIGS. 4-6, 7A-10A, 7B to 10B, 11, and 12.

Referring to FIGS. 13A and 13B, on a resultant structure of FIG. 6, the first liner dielectric layer 111, the second liner dielectric layer 113, and the buried dielectric layer 115 may be partially removed to form a device isolation structure STI positioned in the device isolation trench ST. For example, both of the second liner dielectric layer 113 and the buried dielectric layer 115 may be partially removed to expose a top surface 112u of the first liner dielectric layer 111. Alternatively, all of the first liner dielectric layer 111, the second liner dielectric layer 113, and the buried dielectric layer 115 may be partially removed to expose the top surface of the semiconductor substrate 100.

Typically, in a comparative example, a wet etching process may be performed to remove a portion of the second liner dielectric layer 113 and a portion of the buried dielectric layer 115. The wet etching process may continue until the top surface 112u of the first liner dielectric layer 111 is exposed or the top surface of the semiconductor substrate 100 is exposed. In this case, the first liner dielectric layer 111, the second liner dielectric layer 113, and the buried dielectric layer 115 may include different materials, and may have different etch rates with respect to an etchant used in the wet etching process. For example, the second liner dielectric layer 113 formed of silicon nitride (SiN) may have an etch rate greater than those of the first liner dielectric layer 111 and the buried dielectric layer 115 each of which is formed of silicon oxide (SiO) or silicon oxynitride (SiON). Therefore, after the termination of the wet etching process, a first liner dielectric pattern 112, a second liner dielectric pattern 114, and a buried dielectric pattern 116 may respectively have top surfaces 112u, 114u, and 116u that are located at different levels from each other. For example, the top surface 114u of the second liner dielectric pattern 114 may be located at a lower level than that of the top surface 112u of the first liner dielectric pattern 112 and that of the top surface 116u of the buried dielectric pattern 116, and the top surface 114u of the second liner dielectric pattern 114 may form a first recess RS1 depressed from the top surface 112u of the first liner dielectric pattern 112 and the top surface 116u of the buried dielectric pattern 116.

Alternatively, as shown in FIG. 2C, the second liner dielectric pattern 114 may completely fill the device isolation trench ST between the active regions ACT that are adjacent to each other in the first direction D1. In this case, the top surface 114u of the second liner dielectric pattern 114 may be located at a lower level between the top surfaces 112u of the first liner dielectric patterns 112, and may form a recess depressed from the top surface 112u of the first liner dielectric pattern 112.

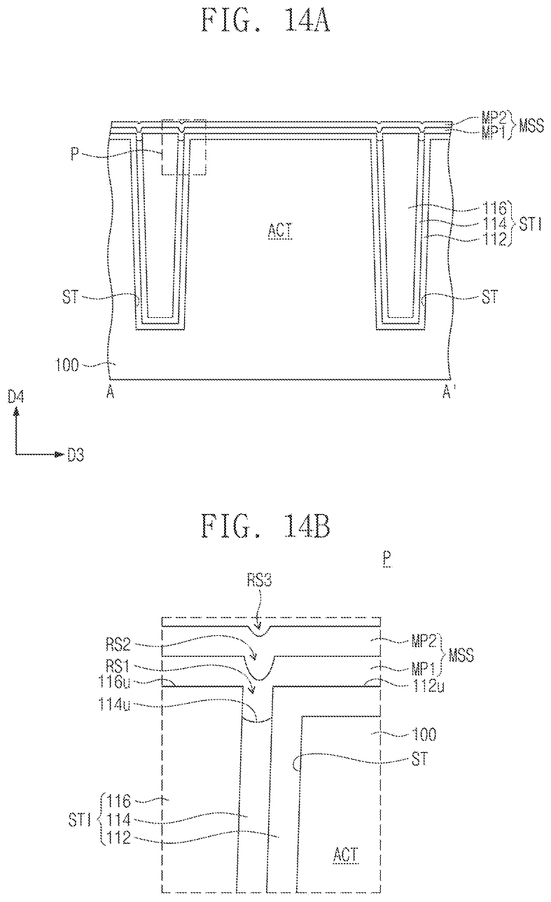

Referring to FIGS. 14A and 14B, a first mask pattern MP1 may be formed on the semiconductor substrate 100. The first mask pattern MP1 may be formed by a low-temperature atomic layer deposition (LT-ALD) process. A top surface of the first mask pattern MP1 may have a flat part and a second recess RS2 depressed from the flat part. For example, when the first mask pattern MP1 is formed, a dielectric material of the first mask pattern MP1 may be introduced into the first recess RS1, and therefore the top surface of the first mask pattern MP1 may be recessed on (e.g., above) the top surface 114u of the second liner dielectric pattern 114. The second recess RS2 may have a depth less than that of the first recess RS1. Thus, a vertical thickness of the first mask pattern MP1 may be thicker on the top surface 114u of the second liner dielectric pattern 114 than on the top surface 112u of the first liner dielectric pattern 112 or the top surface 116u of the buried dielectric pattern 116.

A second mask pattern MP2 may be formed on the first mask pattern MP1. The second mask pattern MP2 may be formed by a chemical vapor deposition (CVD) process. A top surface of the second mask pattern MP2 may have a flat part and a third recess RS3 depressed from the flat part. For example, when the second mask pattern MP2 is formed, a dielectric material of the second mask pattern MP2 may be introduced into the second recess RS2, and therefore the top surface of the second mask pattern MP2 may be recessed on (e.g., above) the top surface 114u of the second liner dielectric pattern 114. The third recess RS3 may have a depth less than that of the second recess RS2. Thus, a vertical thickness of the second mask pattern MP2 may be thicker on the top surface 114u of the second liner dielectric pattern 114 than on the top surface 112u of the first liner dielectric pattern 112 or the top surface 116u of the buried dielectric pattern 116.

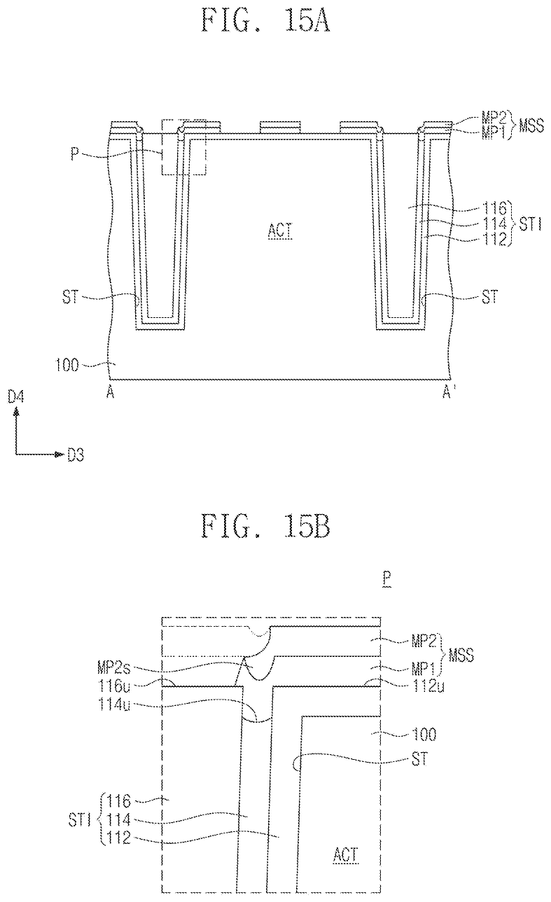

Referring to FIGS. 15A and 15B, pattern holes PH may be formed in the mask structure MSS. For example, after the second mask pattern MP2 is patterned, the second mask pattern MP2 may be used as an etching mask to pattern the first mask pattern MP1 to form the pattern holes PH that vertically penetrate the second mask pattern MP2 and the first mask pattern MP1.

As shown in FIGS. 15A and 15B, when the first recess RS1 is formed on the second liner dielectric pattern 114, the second recess RS2 and the third recess RS3 may be respectively formed on the first mask pattern MP1 and the second mask pattern MP2, and the first mask pattern MP1 and the second mask pattern MP2 may have their non-flat shapes and irregular thicknesses. Therefore, when the second mask pattern MP2 is patterned, a portion of the second mask pattern MP may not be removed but may remain on the first recess RS1 or the second recess RS2, and the portion of the second mask pattern MP2 may serve as a mask in a process where the first mask pattern MP1 is patterned. For example, as shown in FIG. 15B, the second mask pattern MP2 may have a residue MP2S that fills the second recess RS2. As discussed above, a mask pattern residue may unintentionally remain on the first recess RS1, and thus gate trenches T1 and T2 may not be formed into required shapes. For example, when the mask pattern residue is present on the buried dielectric pattern 116 or the second liner dielectric pattern 114, gate trenches T1 and T2 may have widths less than required or may be cut.

According to some embodiments of the present inventive concepts as shown, e.g., in FIGS. 4-12, the first liner dielectric pattern 112, the second liner dielectric pattern 114, and the buried dielectric pattern 116 may be formed to respectively have their top surfaces 112u, 114u, and 116u that are substantially flat and coplanar with each other. For example, a chemical mechanical polishing (CMP) process may be performed in which the first liner dielectric pattern 112, the second liner dielectric pattern 114, and the buried dielectric pattern 116 may be removed to form a device isolation structure STI. The first mask pattern MP1 and the second mask pattern MP2 may have their flat shapes and uniform thicknesses. As a result, there may be provided a method of fabricating a semiconductor device with less occurrence of failure.

In contrast, in a comparative example shown in FIGS. 13A-16B, when the second mask pattern MP2 is patterned using a wet etching process instead of a CMP process, a mask pattern residue may unintentionally remain on the second liner dielectric pattern 114, and thus gate trenches T1 and T2 may not be formed into required shapes.

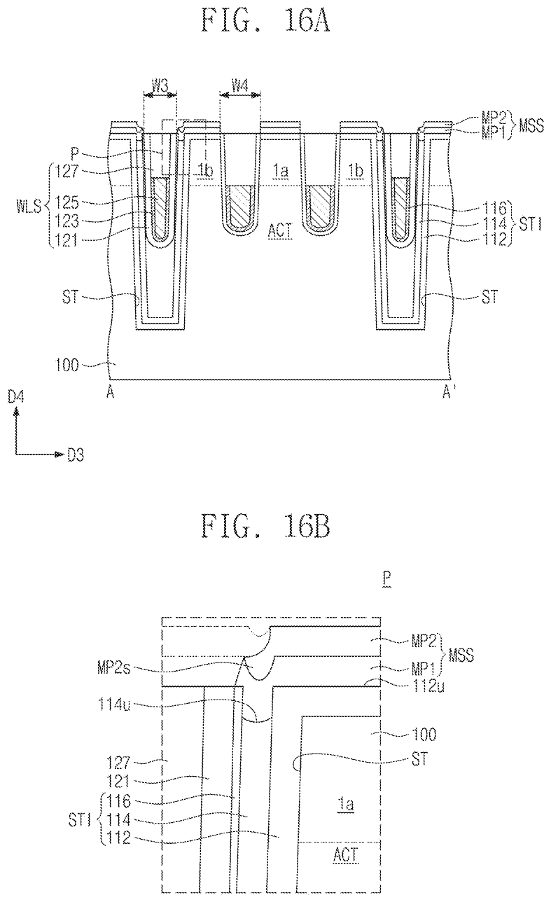

Referring to FIGS. 16A and 16B, gate trenches T1 and T2 may be formed in the semiconductor substrate 100. The gate trenches T1 and T2 may be formed by using the mask structure MSS to pattern portions of the active regions ACT and portions of the device isolation structure STI. For example, the formation of the gate trenches T1 and T2 may include using the mask structure MSS as an etching mask to anisotropically etch the semiconductor substrate 100. In the anisotropic etching process, the device isolation structure STI and the active regions ACT may be partially etched. For example, the second mask pattern MP2 may be used to firstly etch the semiconductor substrate 100, the second mask pattern MP2 may be removed, the first mask pattern MP1 may be used to secondly etch the semiconductor substrate 100, and then the first mask pattern MP1 may be removed. In this case, the portion MP2S of the second mask pattern MP2 may remain in the second recess RS2, and thus as discussed above, the gate trenches T1 and T2 may be formed to have their widths less than required or may be cut.

In the anisotropic etching process, a difference in material may cause the first trenches T1 having a first depth to be formed on the active regions ACT and the second trenches T2 having a second depth, which is greater than the first depth, to be formed on the device isolation structure STI. The second trenches T2 may have their bottom surfaces located at a lower level than that of a top surface of the first liner dielectric pattern 112. The gate trenches T1 and T2 may have their widths each of which is less than a distance between the active regions ACT that are adjacent to each other in the third direction D3 (or a width of the device isolation structure STI). For example, the word-line structures WLS may have irregular widths, and one of the word-line structures WLS may have a width W3 less than a width W4 of another of the word-line structures WLS or the word-line structures WLS may be cut.

In a semiconductor device according to some embodiments of the present inventive concepts, gate trenches and word-line structures may have their uniform thicknesses, and thus the word-line structures may have their resistances that are uniform irrespective of position. Therefore, a semiconductor device may be provided with uniform electrical signals applied to transistors therein, and may have improved electrical properties.

In a method of fabricating a semiconductor device according to some embodiments of the present inventive concepts, a first liner dielectric pattern, a second liner dielectric pattern, and a buried dielectric pattern may be formed to have their top surfaces that are substantially flat and coplanar with each other. For example, a chemical mechanical polishing (CMP) process may be performed in which the first liner dielectric pattern, the second liner dielectric pattern, and the buried dielectric pattern may be partially removed to form a device isolation structure. Therefore, a first mask pattern and a second mask pattern may have their flat shapes and uniform thicknesses. When the second mask pattern is patterned, a mask pattern residue may unintentionally remain on the second liner dielectric layer, and thus gate trenches may not be formed into required shapes. As a result, there may be provided a method of fabricating a semiconductor device with less occurrence of failure.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A method of fabricating a semiconductor device, the method comprising:
forming, in a semiconductor substrate, a device isolation trench that defines active regions;
forming a first liner dielectric layer that conformally covers a top surface of the semiconductor substrate and an inner wall of the device isolation trench;
forming a second liner dielectric layer that conformally covers the first liner dielectric layer;
forming, on the semiconductor substrate, a buried dielectric layer that fills the device isolation trench;
performing a polishing process on the second liner dielectric layer and the buried dielectric layer to form a device isolation structure;
forming, on the semiconductor substrate, a mask pattern that runs across the active regions; and
using the mask pattern to pattern portions of the active regions and portions of the device isolation structure to form gate trenches,
wherein, after the polishing process, a top surface of the first liner dielectric layer, a top surface of the second liner dielectric layer, and a top surface of the buried dielectric layer formed by the polishing process are coplanar with each other.

2. The method of claim 1, wherein the forming of the mask pattern includes:
forming a first mask layer on the semiconductor substrate;
forming a second mask layer on the first mask layer; and
forming a pattern from the first mask layer and the second mask layer, the pattern exposing the portions of the active regions and the portions of the device isolation structure, and
wherein the first mask layer and the second mask layer have a plate shape.

3. The method of claim 2, wherein, above the top surface of the second liner dielectric layer formed by the polishing process, a top surface of the first mask layer and a top surface of the second mask layer are substantially flat.

4. The method of claim 2, wherein the forming of the gate trenches includes:
performing a first etching process on the active regions and the device isolation structure by using the second mask layer in which the pattern is formed;
removing the second mask layer; and
performing a second etching process on the active regions and the device isolation structure by using the first mask layer in which the pattern is formed.

5. The method of claim 1, wherein, after the polishing process, a first distance between a bottom surface of the semiconductor substrate and the top surface of the first liner dielectric layer is substantially the same as a second distance between the bottom surface of the semiconductor substrate and the top surface of the second liner dielectric layer and a third distance between the bottom surface of the semiconductor substrate and the top surface of the buried dielectric layer.

6. The method of claim 1, wherein
the first liner dielectric layer includes silicon oxide (SiO), and
the second liner dielectric layer includes silicon nitride (SIN).

7. The method of claim 1, wherein the polishing process includes a chemical mechanical polishing (CMP) process.

8. The method of claim 7, wherein slurry used in the chemical mechanical polishing process has an etch selectivity with respect to the first liner dielectric layer and the second liner dielectric layer.

9. The method of claim 1,
wherein the gate trenches run in a first direction across the active regions on the semiconductor substrate, and
wherein a width in a second direction of the gate trenches is uniform along the first direction, the second direction being orthogonal to the first direction.

10. The method of claim 1, further comprising:
forming word-line structures in the gate trenches;
forming impurity regions in the active regions on opposite sides of each of the word-line structures;
forming an interlayer dielectric layer on an entire surface of the semiconductor substrate;
patterning the interlayer dielectric layer and the semiconductor substrate to form contact recesses that expose a central portion of each of the active regions; and
forming bit-line structures in the contact recesses.

11. A method of fabricating a semiconductor device, the method comprising:
forming, in a semiconductor substrate, a device isolation trench that defines active regions;
forming a first liner dielectric layer that conformally covers a top surface of the semiconductor substrate and an inner wall of the device isolation trench;
forming a second liner dielectric layer that conformally covers the first liner dielectric layer;
forming, on the semiconductor substrate, a buried dielectric layer that fills the device isolation trench;
performing a polishing process on the second liner dielectric layer and the buried dielectric layer to form a device isolation structure, wherein the polishing process continues until a top surface of the first liner dielectric layer is exposed;
forming a first mask pattern on the semiconductor substrate and a second mask pattern on the first mask pattern, wherein the same pattern is formed in the first mask pattern as in the second mask pattern;
performing a first etching process on the active regions and the device isolation structure by using the second mask pattern;
removing the second mask pattern; and
perform a second etching process on the active regions and the device isolation structure by using the first mask pattern,
wherein, after the polishing process, the top surface of the first liner dielectric layer and a top surface of the second liner dielectric layer are at the same vertical level, and
wherein the first and second etching processes are performed such that portions of the active regions and portions of the device isolation structure are patterned to form gate trenches.

12. The method of claim 11, wherein, after the polishing process, the top surface of the first liner dielectric layer, the top surface of the second liner dielectric layer, and a top surface of the buried dielectric layer are coplanar with each other.

13. The method of claim 11, wherein the first mask pattern and the second mask pattern have a plate shape.

14. The method of claim 13, wherein a top surface of the first mask pattern and a top surface of the second mask pattern are substantially flat.

15. The method of claim 11, wherein
the first liner dielectric layer includes silicon oxide (SiO), and
the second liner dielectric layer includes silicon nitride (SiN).

16. The method of claim 11, wherein the polishing process includes a chemical mechanical polishing (CMP) process, and
wherein slurry used in the chemical mechanical polishing process has an etch selectivity with respect to the first liner dielectric layer and the second liner dielectric layer.

17. The method of claim 11,
wherein the gate trenches run in a first direction across the active regions on the semiconductor substrate, and
wherein a width in a second direction of the gate trenches is uniform along the first direction, the second direction being orthogonal to the first direction.

18. A method of fabricating a semiconductor device, the method comprising:
forming, in a semiconductor substrate, a device isolation trench that defines active regions;
forming a first liner dielectric layer that conformally covers a top surface of the semiconductor substrate and an inner wall of the device isolation trench;
forming a second liner dielectric layer that conformally covers the first liner dielectric layer;
forming, on the semiconductor substrate, a buried dielectric layer that fills the device isolation trench;
performing a polishing process on the second liner dielectric layer and the buried dielectric layer to form a device isolation structure, wherein the polishing process continues until a top surface of the second liner dielectric layer and a top surface of the first liner dielectric layer are located at the same vertical level;
forming, on the semiconductor substrate, a mask pattern that runs across the active regions; and
patterning portions of the active regions and portions of the device isolation structure to form gate trenches by using the mask pattern,
wherein the gate trenches run in a first direction across the active regions on the semiconductor substrate, and
wherein a width in a second direction of the gate trenches is uniform along the first direction, the second direction being orthogonal to the first direction.

19. The method of claim 18, wherein, after the polishing process, the top surface of the first liner dielectric layer, the top surface of the second liner dielectric layer, and a top surface of the buried dielectric layer are substantially flat and coplanar with each other.

20. The method of claim 18, wherein the polishing process includes a chemical mechanical polishing (CMP) process, and
wherein slurry used in the chemical mechanical polishing process has an etch selectivity with respect to the first liner dielectric layer and the second liner dielectric layer.
